(19) United States
(12) Patent Application Publication
(10) Pub. No.: US 2012/0313201 A1
(43) Pub. Date: Dec. 13, 2012

(54) OPTICAL SENSOR DEVICES INCLUDING FRONT-END-OF-LINE (FEOL) OPTICAL FILTERS AND METHODS FOR FABRICATING OPTICAL SENSOR DEVICES

(75) Inventors: Francois Hebert, San Mateo, CA (US); Jonathan Herman, Los Gatos, CA (US); I-Shan Sun, San Jose, CA (US)

(73) Assignee: INTERSIL AMERICAS LLC, Milpitas, CA (US)

(21) Appl. No.: 13/466,867

(22) Filed: May 8, 2012

Related U.S. Application Data
(60) Provisional application No. 61/496,336, filed on Jun. 13, 2011.
(60) Provisional application No. 61/534,314, filed on Sep. 13, 2011.

(51) Int. Cl. H01L 31/0232; H01L 31/18

(52) U.S. Cl. 257/432; 438/70; 257/E31.127

(57) ABSTRACT

Optical sensor devices, and methods of manufacturing the same, are described herein. In an embodiment, a monolithic optical sensor device includes a semiconductor substrate having a trench, with a photodetector region under said trench. An optical filter is formed in the trench and over at least a portion of the photodetector region. One or more metal structures extend above a top surface of said optical filter. The trench, photodetector region and optical filter are formed as part of a front-end-of-line (FEOL) semiconductor fabrication process. The one or more metal structures are formed as part of a back-end-of-line (BEOL) semiconductor fabrication process.

### PRIORITY CLAIMS

This application claims priority under 35 U.S.C. 119(e) to U.S. Provisional Patent Application No. 61/496,336, entitled FRONT-END OPTICAL FILTER DEVICES AND FABRICATION METHODS, filed Jun. 13, 2011, and U.S. Provisional Patent Application No. 61/534,314, entitled OPTICAL SENSOR DEVICES INCLUDING FRONT-END-OF-LINE (FEOL) OPTICAL FILTERS AND METHODS FOR FABRICATING OPTICAL SENSOR DEVICES, filed Sep. 23, 2011, both of which are incorporated herein by reference.

### BACKGROUND

Photodetectors can be used for various different types of applications, including, but not limited to, for ambient light sensor (ALS) applications, for proximity sensor applications, and for use in long range sensing applications. Such applications typically require high performance optical filters. For example, for ALS applications, an optical filter is typically used to modify the spectral response of a photodetector so that the photodetector and filter achieve a spectral response that is very similar to that of a typical human eye. Such a response can be referred to as a “true human eye” response.

Typically, organic based optical filters can not be used to provide such a true human eye response, because of their poor performance in the infrared range. Rather, non-organic filters, such as filters made of dielectric mirrors, are generally preferred because they provide better performance. Such dielectric mirrors, which are made from stacks of various dielectric films, are conventionally expensive to implement. This is because they are typically deposited during post processing of wafers (i.e., after wafers are completed by a foundry). For example, since foundries typically don't have the expertise and equipment to manufacture such optical filters, specialty vendors often use customized equipment to add such optical filters to wafers or dies.

### BRIEF DESCRIPTION OF THE DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 is a cross-sectional side view of an optical sensor device according to one embodiment.

FIG. 2 is a cross-sectional side view of an optical sensor device according to another embodiment.

FIG. 3 is a cross-sectional side view of an optical sensor device according to a further embodiment.

FIG. 4 is a cross-sectional side view of an optical sensor device according to another embodiment.

FIGS. 5A-5C show top views of various exemplary embodiments of metal grid patterns that can be implemented in an optical sensor device.

FIG. 6 is a cross-sectional side view of an optical sensor array according to one embodiment.

FIG. 7 is a cross-sectional side view of an optical sensor array according to another embodiment.

FIG. 8 is a cross-sectional side view of an optical sensor device according to a further embodiment.

FIGS. 9A-9J illustrate various stages in a method of fabricating an optical sensor device according to one approach.

FIGS. 10A-10D illustrate various stages in a method of fabricating an optical sensor device according to another approach.

FIGS. 11A-11D illustrate various stages in a method of fabricating an optical sensor device according to an alternative approach.

FIG. 12 illustrates a stage in a method of fabricating an optical sensor device according to a further approach.

FIG. 13 is a high level flow diagram used to summarize various methods for fabricating an optical sensor device in accordance with various embodiments of the present invention.

FIG. 14 is a high level block diagram of a system that includes an optical sensor device according to an embodiment of the present invention.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration specific illustrative embodiments. It is to be understood that other embodiments may be utilized and that mechanical and electrical changes may be made. The following detailed description is, therefore, not to be taken in a limiting sense. In the description that follows, like numerals or reference designators will be used to refer to like parts or elements throughout. In addition, the first digit of a reference number identifies the drawing in which the reference number first appears.

Optical sensor devices including front-end-of-line (FEOL) formed optical filters, and fabrication methods for such optical sensor devices, are provided. In the optical sensor devices, the optical filters are formed prior to metallization of the devices. In specific embodiments, the optical filter is composed of a layered stack of dielectric materials that are compatible with high-temperature processing, standard deposition equipment, and standard patterning equipment (definition and etch). The optical filter can be coplanar or non-planar, relative to an active surface of the device. Metal structures such as grids and columns can be patterned over the optical filter.

The optical sensor devices can be employed as various sensors such as ambient light sensors and proximity sensors, or in long range sensing applications that require high performance optical filters.

The optical filter dielectric materials can include silicon dioxide (SiO2), silicon hydride (SixHy), silicon nitride (SixNy), silicon oxynitride (SixOzNy), tantalum oxide (TaxOy), gallium arsenide (GaAs), gallium nitride (GaN), and the like.

Various conventional deposition methods can be employed in fabricating the optical filters, such as chemical vapor deposition (CVD), plasma-enhanced CVD (PECVD), low-pressure CVD (LPCVD), metalorganic CVD (MOCVD), molecular beam epitaxy (MBE), epitaxy, evaporation, sputtering, physical vapor deposition (PVD), atomic layer deposition (ALD), in-situ jet vapor deposition (JVD), and the like.

In certain embodiments, the optical filter is composed of dielectric mirrors, which are formed from layered stacks of various dielectric films. More specifically, the dielectric mirrors can be formed of alternating dielectric layers with different optical properties. For example, an oxide and nitride (e.g., SiO₂ and Si₃N₄) can be formed in alternating layers to produce the dielectric mirrors.

The optical filter can be formed directly on top of a photodetector region (also referred to as an optical sensor region) that includes a photo-sensor such as a PN junction or PIN junction photo-diode. The optical filter is formed prior to (and thus, under) metallization on semiconductor wafers. The optical filter can have a surface substantially coplanar with the surface of active devices, which can be referred to as the active device surface. In addition, various structures can be formed on top of the optical filter to shield the edges of the filter, as well as direct and/or block light. In addition, multiple sensors can be formed on the same die with coplanar optical filters formed under the metallization.

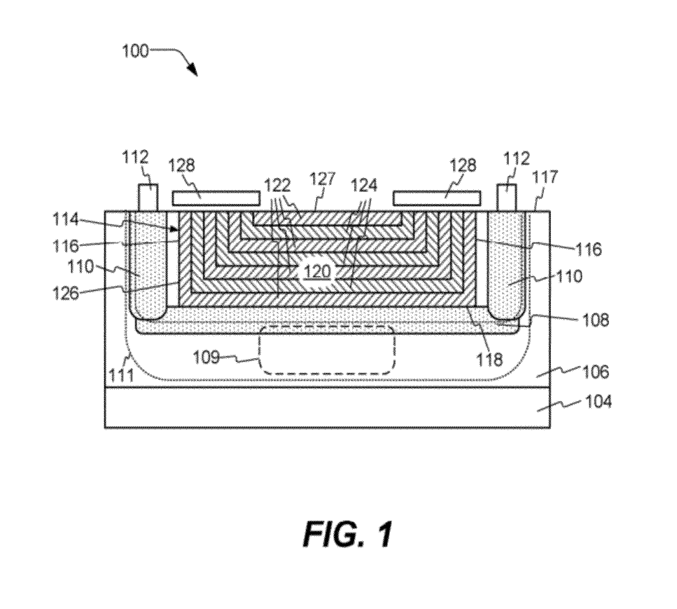

FIG. 1 is a cross-sectional side view of an optical sensor device 100 according to one embodiment. The sensor device 100 has a substantially planar structure, and has an optical filter 120 formed in the front-end-of-line (FEOL) of a device fabrication process prior to metallization. By contrast, metallization is part of the back-end-of-line (BEOL) of a device fabrication process. The sensor device 100 is monolithic, meaning that the entire sensor device including the photodetector region and the optical filter 120 is built into a single die on a wafer. Such a monolithic sensor device can also include analog front-end (AFE) circuitry integrated with a photodetector region and the optical filter 120. The sensor device 100 includes a semiconductor substrate 104, and a further semiconductor substrate 106 over the semiconductor substrate 104. A diffusion/implant layer 108 is formed in the substrate 106. FIG. 1 also shows an exemplary depletion region, generally shown by dotted line region labeled 111, which is formed when a PN or PIN junction is reverse biased using a voltage source. The photodetector region, which converts light into a current, is generally shown by the dashed line region labeled 109.

In accordance with an embodiment, the semiconductor substrate 104 is a P+ anode substrate, and the semiconductor substrate 106 is a P-type epitaxial layer or a P-type substrate that is low doped for low capacitance. In accordance with an embodiment, the low doping concentration of carriers in the P-substrate 106 is less than 1×10¹⁵ atoms/cm³, and preferably about 1×10¹³ atoms/cm³. Additionally, the thickness of the substrate 106 is preferably between about 5 microns and 30 microns, and preferably about 20 microns. By contrast, the doping concentration of carriers in the P+ substrate 104 is between about 1×10¹⁷ atoms/cm³ and about 1×10¹⁹ atoms/cm³, and preferably about 1×10¹⁸ atoms/cm³. In such an embodiment, the carriers would preferably be fully depleted at a charge of about 1 Volt. In this embodiment, the layer 108 is a cathode layer, such as an N+ diffusion/implant layer, that is formed in the second substrate 106. An N-well region 110 in the second substrate 106 connects the cathode layer 108 to one or more metal surface connectors 112. For the remainder of the description, it will be assumed that the layers 104, 106 and 108 have the polarities described above. However, it is also within the scope of the present invention for the polarities to be reversed, i.e., for the semiconductor substrate 104 to be an N+ cathode substrate, the semiconductor substrate 106 to be an N-type epitaxial layer or a N-type substrate that is low doped for low capacitance, the layer 108 to be a P+ anode layer, and the wells 110 to be P-wells.

The substrate 106 includes a trench 114 that extends downward from a top surface 117 of the substrate 106. In FIG. 1, the trench 114 is shown as including vertical sidewalls 116 that are substantially perpendicular to the top surface 117 of the substrate 106. Additionally, the trench 114 is shown as having a bottom 118 that is substantially parallel to the top surface 117 of the substrate 106 and substantially perpendicular to the sidewalls 116 of the trench 114. Where one or more active devices (e.g., transistors) are built into the same die as the optical sensor device 100, and the top surface 117 is the active surface of the active device(s), the top surface 117 can also be referred to as an active surface 117.

The optical filter 120 is formed within the trench 114, and in accordance with an embodiment, a top surface 127 of the optical filter 120 is coplanar with the top surface 117 of the substrate 106.

In accordance with an embodiment, the optical filter 120 comprises a stack of alternating dielectric layers 122 and 124, which are formed over the cathode layer 108 such that the cathode layer 108 is adjacent to the bottom of the filter stack. The optical filter 120 is formed to have a vertical sidewall 126. In one embodiment, optical filter 120 can include alternating layers of an oxide and a nitride (e.g., SiO₂ and Si₃N₄) at preselected thicknesses, which form dielectric mirrors.

In FIG. 1, a lateral shield layer 128 is located over the periphery of the optical filter 120 to block light. The shield layer 128 blocks light from penetrating at the periphery of optical filter 120. The shield layer 128 can be formed of polysilicon (e.g., a gate layer), polysilicides, or metal interconnect layers.

A top surface of the optical sensor device 100 can optionally have a passivation layer, which is etched to expose the optical filter 120. In addition, an optional etch stop layer can be formed in the layers of the optical filter 120.

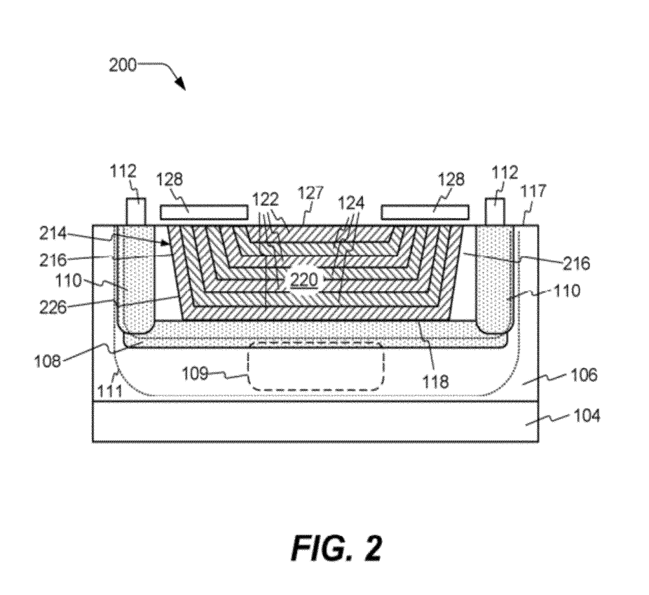

FIG. 2 is a cross-sectional side view of an optical sensor device 200 according to another embodiment. The sensor device 200 has structural features similar to sensor device 100, including a substantially planar structure and an optical filter 220 formed in the FEOL of a device fabrication process prior to metallization. The main difference between the optical sensor device 200 and the optical sensor device 100, is that the trench 214 and the optical filter 220 have sloped sidewalls 216 and 226, respectively, in contrast to the vertical sidewalls 116 and 126 of the trench 114 and the optical filter 120, respectively, in FIG. 1. The sloped trench sidewall 226 can be formed using potassium hydroxide (KOH) etching, for example. The optical sensor devices in the remainder of the FIGS. are shown as having trenches and optical filters with vertical sidewalls. However, it is also within the scope of the present invention for any such optical sensor devices to alternatively have a trench and an optical filter with sloped sidewalls.

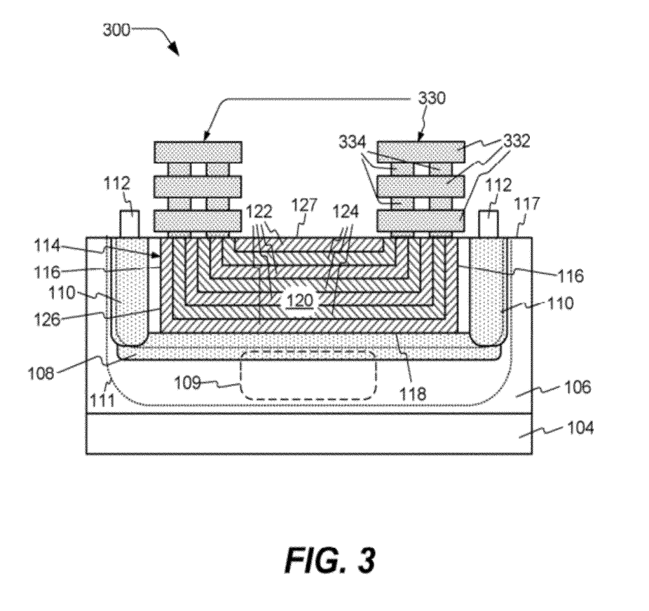

FIG. 3 is a cross-sectional side view of an optical sensor device 300 according a further embodiment. The sensor device 300 has structural features similar to the sensor device 100 of FIG. 1, which features are labeled the same as in FIG. 1. In addition, the sensor device 300 has an opaque grating 330 located on top of and over a portion of the optical filter 120. The grating 330 is formed with a plurality of metal layers 332, which are connected in a stacked configuration with a plurality of metal columns 334, such as vias, contacts, or tungsten plugs. The grating 330 can act as a lateral shield for the periphery of the optical filter 120 to block light.

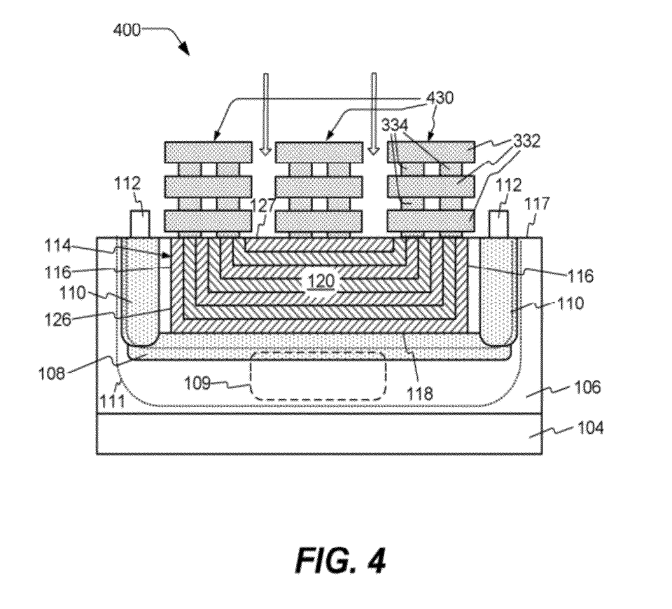

FIG. 4 is a cross-sectional side view of an optical sensor device 400 according to another embodiment. The sensor device 400 has structural features similar to the sensor device 300 of FIG. 3, which features are labeled the same as in FIG. 3. The sensor device 400 also has an opaque grating 430 located on top of and over a portion of the optical filter 120, which is similar to the opaque grating 330, but includes a more dense grid pattern to align light incident on the optical filter 120.

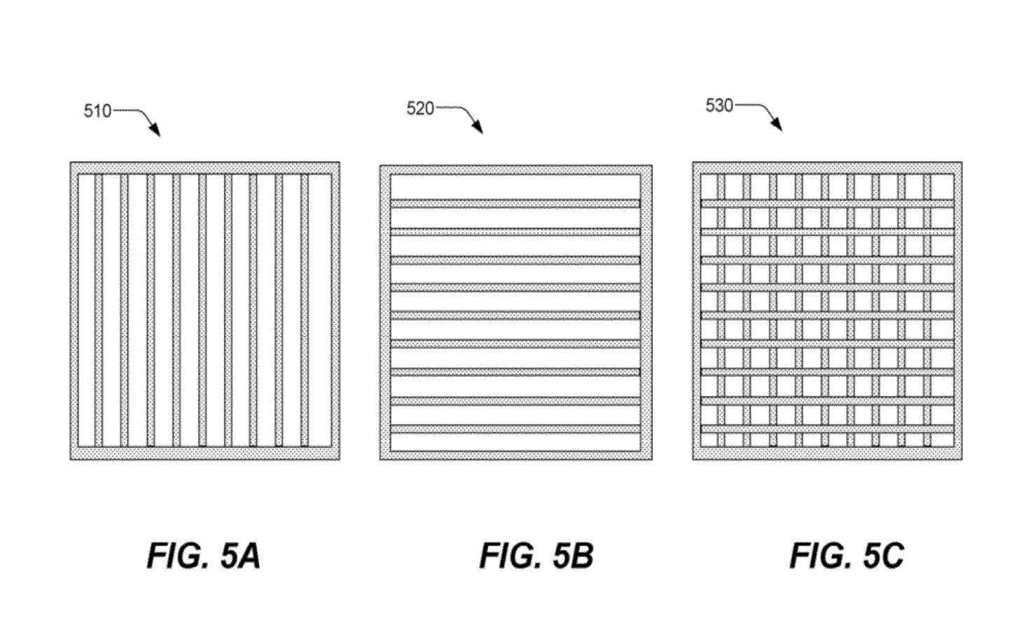

FIGS. 5A-5C show top views of various exemplary embodiments of metal grid patterns that can be implemented in the optical sensor device 400, depending on the application. FIG. 5A depicts a grid pattern 510 in a vertical configuration. FIG. 5B depicts a grid pattern 520 in a horizontal configuration. FIG. 5C depicts a grid pattern 530 having a vertical and horizontal configuration. The grid pattern 510 can be used, for example, to detect when light or an object is moving from left to right, or vice versa. The grid pattern 520 can be used, for example, to detect when light or an object is moving fore to aft, or vice versa. The grid pattern 530 can be used, for example, to detect when light or an object is overhead.

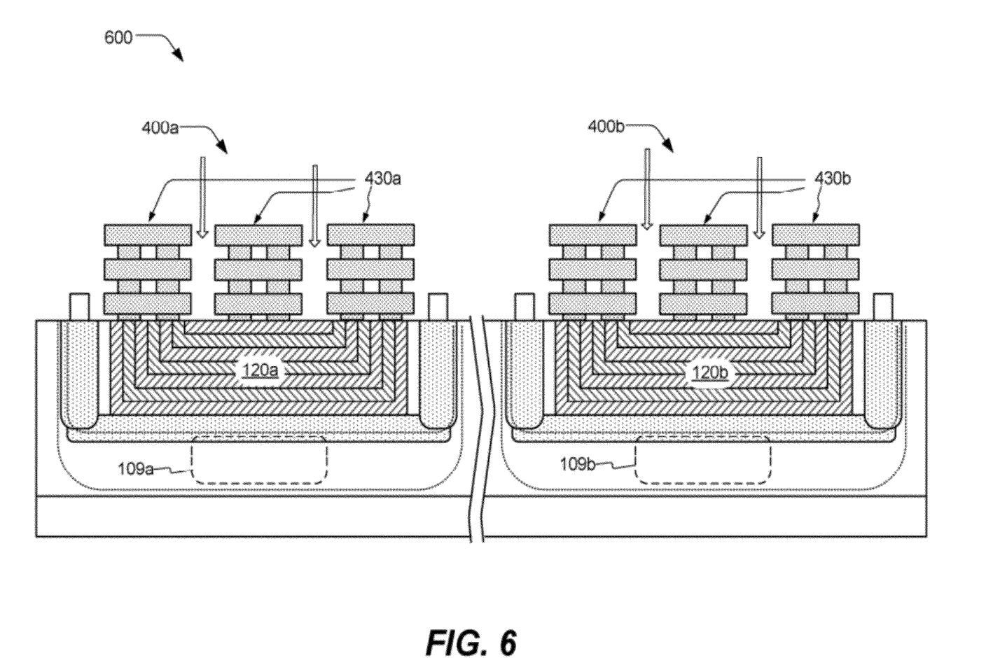

FIG. 6 is a cross-sectional side view of an optical sensor array 600 according to one embodiment. The sensor array 600 includes an optical sensor device 400a and an adjacent optical sensor device 400b formed on the same die. The optical sensor devices 400a and 400b each have structural features similar to those of the optical sensor device 400 of FIG. 4, which features are labeled the same as in FIG. 4. Thus, optical sensor devices 400a and 400b each include a respective photodetector region (generally shown by dashed lined regions 109a and 109b), a respective optical filter 120a, 120b, and a respective opaque grating 430a, 430b.

The pair of optical sensor devices 400a and 400b can provide the optical sensor array 600 with stereo sensing capabilities. In addition the spacing between the optical sensor devices 400a and 400b can be varied to change stereoscopic sensitivity. The pattern of the gratings 430a and 430b can also be optimized as needed such that each pattern can be the same or different for the sensor devices 400a and 400b. For example, a top view of the opaque grating of one of the sensor devices 400a and 400b can resemble the grating pattern 510 in FIG. 5A, while the other one of the sensor devices 400a and 400b can resemble the grating pattern 520 in FIG. 5B. Further, more than two sensor devices can be implemented on the sensor array 600 as needed. For example, a sensor array can include three optical sensor devices, one having a grating having a top view that resembles the grating 510 in FIG. 5A, another having a grating having a top view that resembles the grating 520 in FIG. 5B, and another having a grating having a top view that resembles the grating 530 in FIG. 5C. Other variations are also possible.

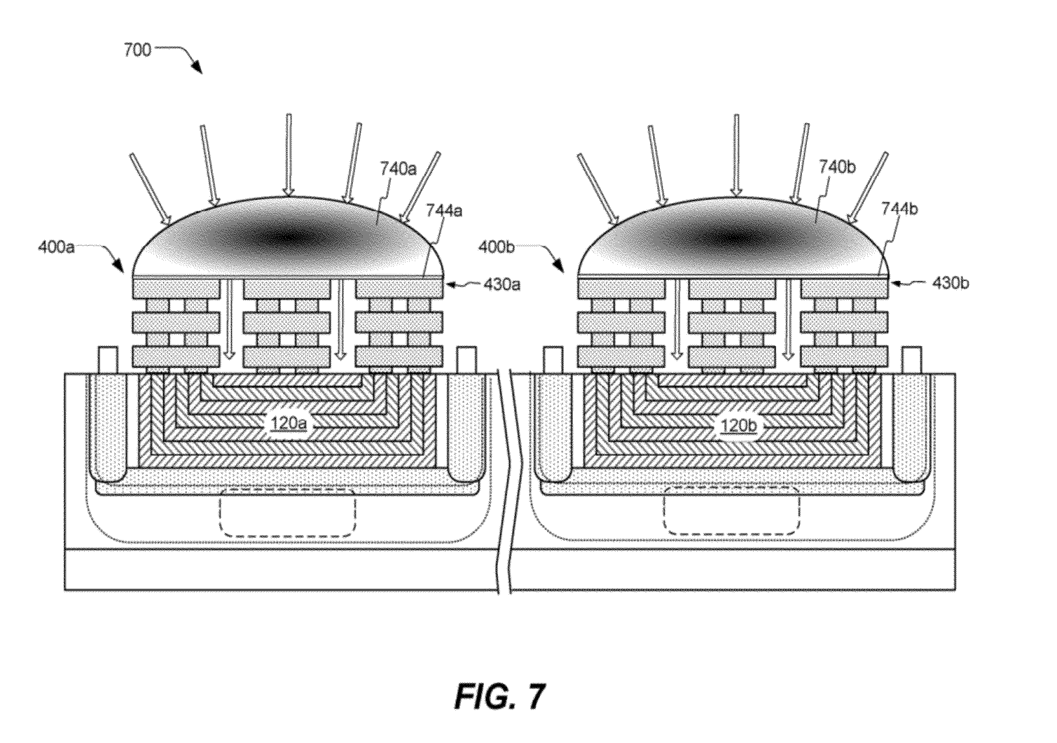

FIG. 7 is a cross-sectional side view of an optical sensor array 700 according to another embodiment. The sensor array 700 has structural features similar to the sensor array 600 discussed above. Thus, sensor array 700 includes an optical sensor device 400a and an adjacent optical sensor device 400b. Each of the sensor devices 400a, 400b also has a respective opaque grating 430a, 430b on top of and over a portion of the respective optical filter 120a, 120b.

The sensor array 700 also includes a micro-lens 740a, 740b over each respective grating 430a, 430b. The micro-lenses 740a, 740b focus light over each of the sensor devices 400a, 400b. The micro-lenses 740a, 740b can be formed on top of a top passivation surface 744a, 744b that is on top of the grating 430a, 430b. In alternative embodiments, a micro-lens can be used on only one of the optical sensor devices, or on additional optical sensor devices when more than two optical sensor devices are implemented in the sensor array 700.

Where multiple optical sensor devices (e.g., 400a and 400b) are included in a same die to form a monolithic sensor array, e.g., as in FIGS. 6 and 7, the optical sensor devices are preferably electrically isolated from one another. Electrical isolation can be achieved, for example, by diffusing rings of alternating N+ and P regions in the silicon around each photo detector region. To improve isolation, the P rings can be grounded, and the N+ rings can be positively biased. Alternatively, or additionally, a field oxide (FOX) isolation region can separate adjacent optical sensor devices. Other electrical isolation techniques are also possible. Further, where multiple optical sensor devices (e.g., 400a and 400b) are included in a same die to form a monolithic sensor array, the optical sensor devices are preferably optically isolated from one another. For example, opaque barriers made of metal and/or poly layers can be formed between adjacent optical sensor devices. In FIGS. 6 and 7, the metal gratings optically isolate the multiple sensor devices.

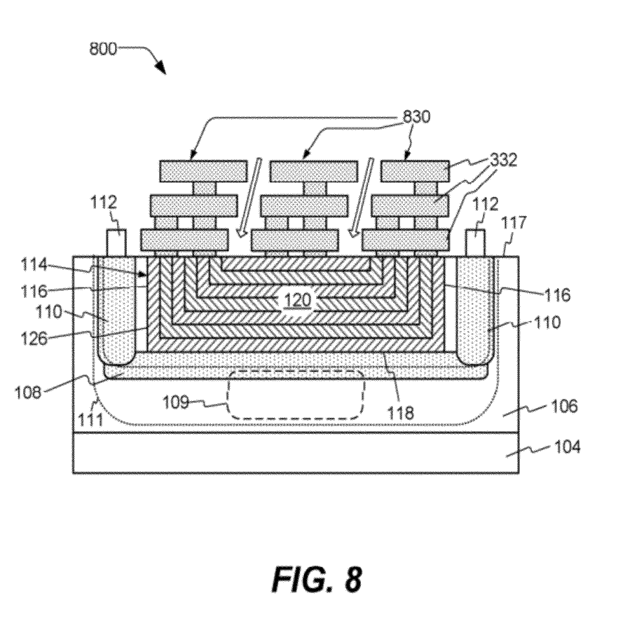

FIG. 8 is a cross-sectional side view of an optical sensor device 800 according a further embodiment. The sensor device 800 has structural features similar to sensor device 400, including a photodetector region and an optical filter 120. The optical sensor device 800 also has an opaque grating 830 located on top of and over a portion of the optical filter 120.

The grating 830 has a “venetian blind” configuration that provides for an angled incidence of light directed to photodetector region 810. The grating 830 also provides a peripheral shield for blocking light from the periphery of optical filter 120. The optical sensor device 800 can be used, for example, to detect light having a specific incidence angle (or range of angles).

The various metal gratings discussed above can be optimized to “filter” light based on a desired incidence angle. In addition, the metal gratings can be configured as “collimators” to align and channel the light to the surface of the photodetector region. The present FEOL formed optical filters can be covered with BEOL formed metal stacks to achieve a desired grating pattern, with no modifications to the process flow of a conventional device fabrication process.

The BEOL dielectric layers, e.g., passivation, inter-metal-dielectrics (IMD), inter-level-dielectrics (ILD), and the like, can be formed over the optical filter 120, after the optical filter 120 is formed in the trench 114. The BEOL dielectric layers, or portions thereof, can thereafter be removed to expose at least a portion of the optical filter 120. For example, a mask and etch approach can be used, such as a dry etch to etch-stop layer formed to protect the top surface 127 of the optical filter 120. The metal stack can also be used as a boundary for the etch as edges of a mask can overlap the metal shield at the edges.

Various methods can be employed in fabricating the optical sensor devices discussed above on a wafer. Such fabrication methods are described with reference to the drawings as follows.

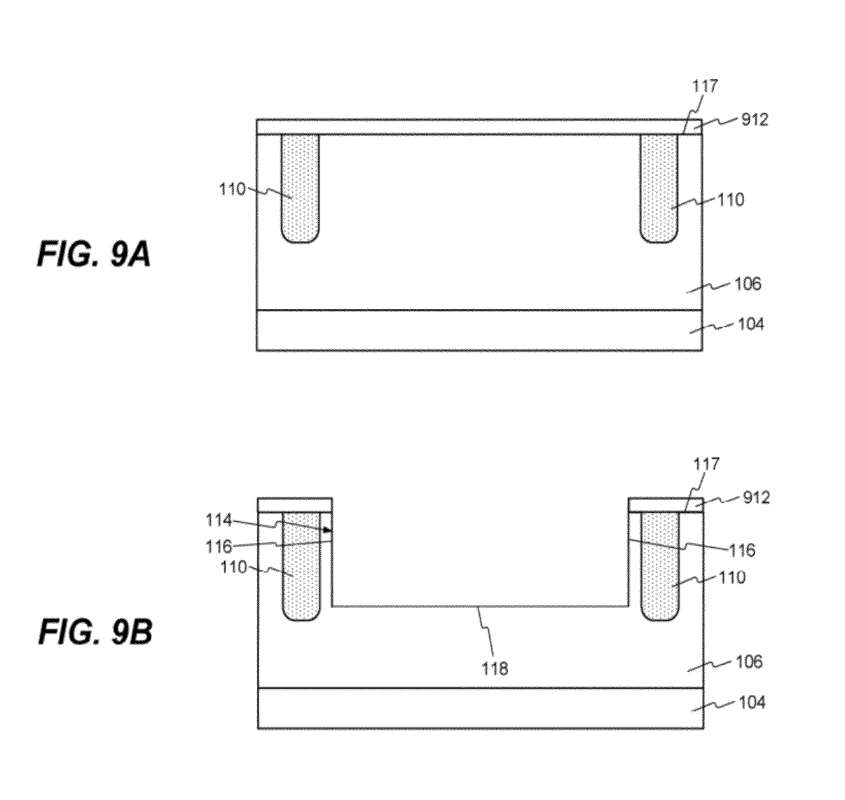

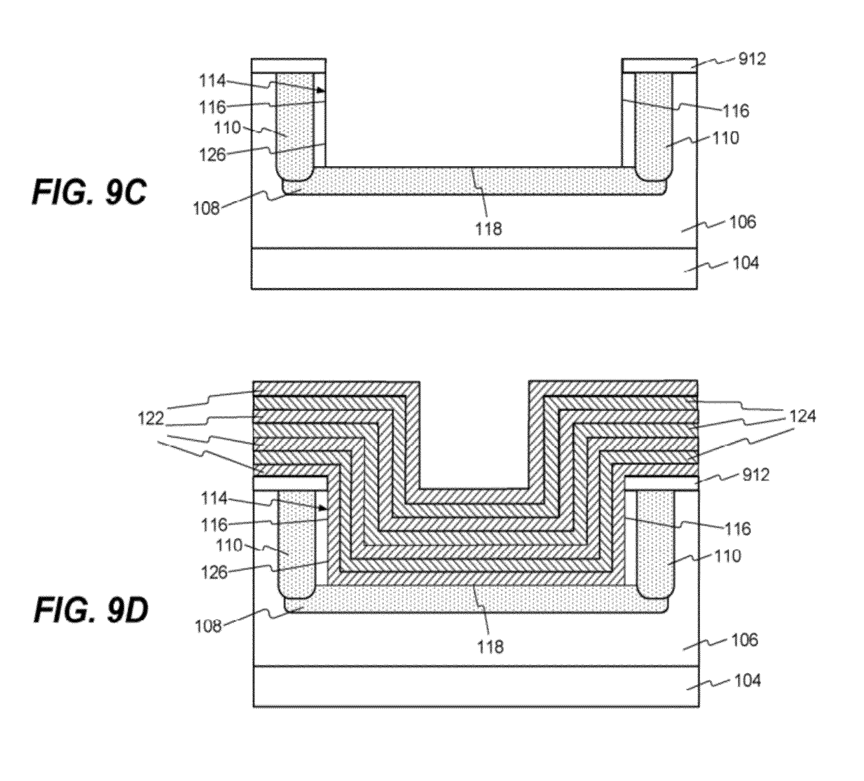

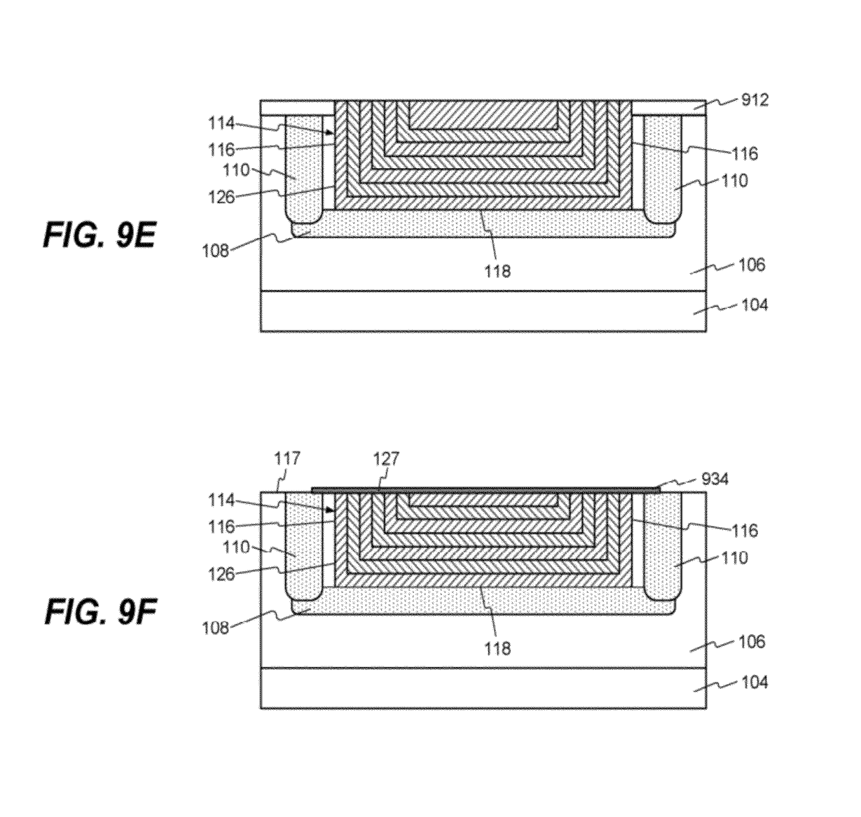

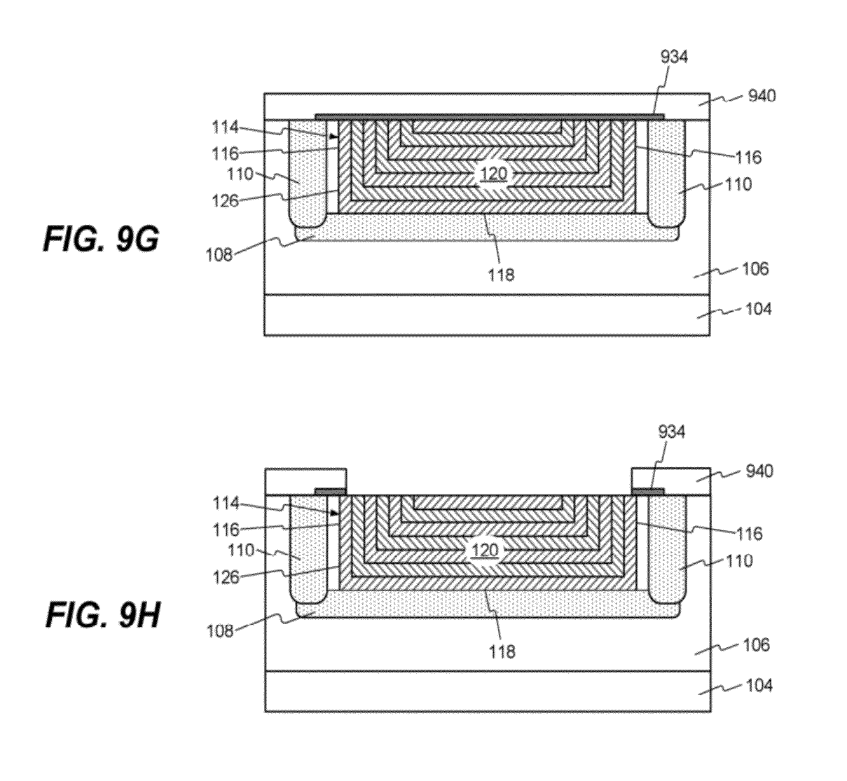

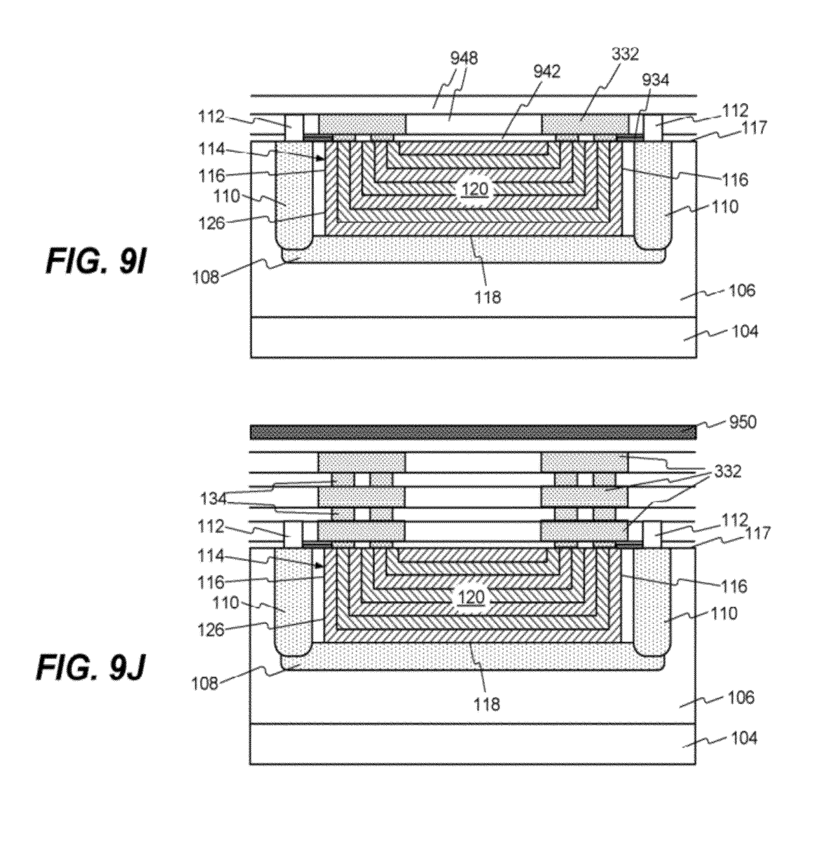

In one fabrication method, a planar optical sensor device 100 is formed having an optical filter with edge shielding, as was shown in FIG. 1. Referring to FIG. 9A, the substrate 104 (such as a P+ anode silicon substrate) is provided, and the substrate 106 (such as a P-type epitaxial layer or a P-type silicon substrate) is formed on the substrate 104. The deep wells regions 110 are formed in the substrate 106 such as by using a standard mask, with N+ implant and diffusion processes. An optional hard mask 912 (such as an oxide layer) can be formed on the upper surface 117 of the substrate 106. The hard mask 912 can also be referred to as a protective layer 912.

Referring to FIG. 9B, a photoresist layer is then patterned to define the trench 114, which is formed by exposure and development of the photoresist layer. A hard mask etch can then be used to remove any hard mask material over the trench 114. A silicon etch is then employed to remove the silicon material of the substrate 106 to form the trench 114, which preferably has a depth equivalent to the desired optical filter thickness.

The cathode layer 108 is then formed in the substrate 106, such as by an N+ cathode implant at the bottom 118 of the trench 114, as shown in FIG. 9C. When used, the hard mask 912 protects the active region including the deep wells regions 110. Wafer cleaning and annealing can then be employed.

As depicted in FIG. 9D, alternating dielectric layers 122 and 124 are then deposited in the trench 114 over the cathode layer 108. At this point, portions of the dielectric layers 122 and 124 also extend above the trench 114 and laterally beyond the trench. When the desired number of dielectric layers 122, 124 have been deposited to form the optical filter 120, an etchback or chemical mechanical polishing (CMP) is performed to planarize the top surface of the optical filter 120, as shown in FIG. 9E. Thereafter, an over etch is performed to remove the hard mask, and further planarization is performed so that the top surface 127 of the optical filter 120 is coplanar with the top surface 117 of the substrate 106. A protection layer 934, such as Si₃N₄, is deposited over the optical filter 120, and the protection layer 934 is patterned, as illustrated in FIG. 9F.

At this point, active devices (if any are to be added to the die) are fabricated for the optical sensor device (or for a separate device on the same die) by conventional methods. This can include completion of any wells or diffusions, active area definition (STI or LOCOS), gate oxide and gate electrode patterning, and source/drain diffusions. The active area definition can be achieved using shallow trench isolation (STI) or local oxidation of silicon (LOCOS), but is not limited thereto. The active devices can be, for example, complementary metal-oxide-semiconductor (CMOS) devices, but are not limited thereto. The CMOS devices and/or other devices are fabricated outside of the photodetector area. One or more interlayer dielectrics (ILDs) 940 and other dielectrics are formed as a result of the device formation and isolation, as shown in FIG. 9G. The area over optical filter 120 is then exposed to selectively remove the ILDs 940 and the protective layer 934, as depicted in FIG. 9H.

After completing the active devices, an ILD 942 is deposited, and a plurality of contacts 112 are formed such as tungsten plugs, which are coupled to deep wells regions 110. A metallization process is then performed by depositing a metal, patterning the metal, and etching the metal to form a metal layer 332. Inter-metal-dielectric layers 948 are then deposited, as shown in FIG. 9I. Additional metal layers 332 and metal columns 334 are then formed to complete the metallization process. A passivation layer 950 is then deposited over the top metal layer 332, and is then patterned as shown in FIG. 9J. A final alloy step is then carried out.

In certain embodiments, the passivation layer 950 and the various dielectric layers 942 and 948 are left intact. In such embodiments, the type and thickness of the passivation layer 950, and types, number and thicknesses of dielectric layers 942 and 948 should be taken into account when designing the optical filter 120 within the trench 114, because these additional layers may affect the optical response of the final optical filter device. For the purpose of this disclosure, the BEOL dielectric layers (e.g., 942 and 948) and the passivation layer 950 are not considered part of the optical filter 120. However, if the BEOL dielectric layers (e.g., 942 and 948) and the passivation layer 950 provide optical filtering, they can be considered part of a BEOL optical filter that is located above the FEOL optical filter 120.

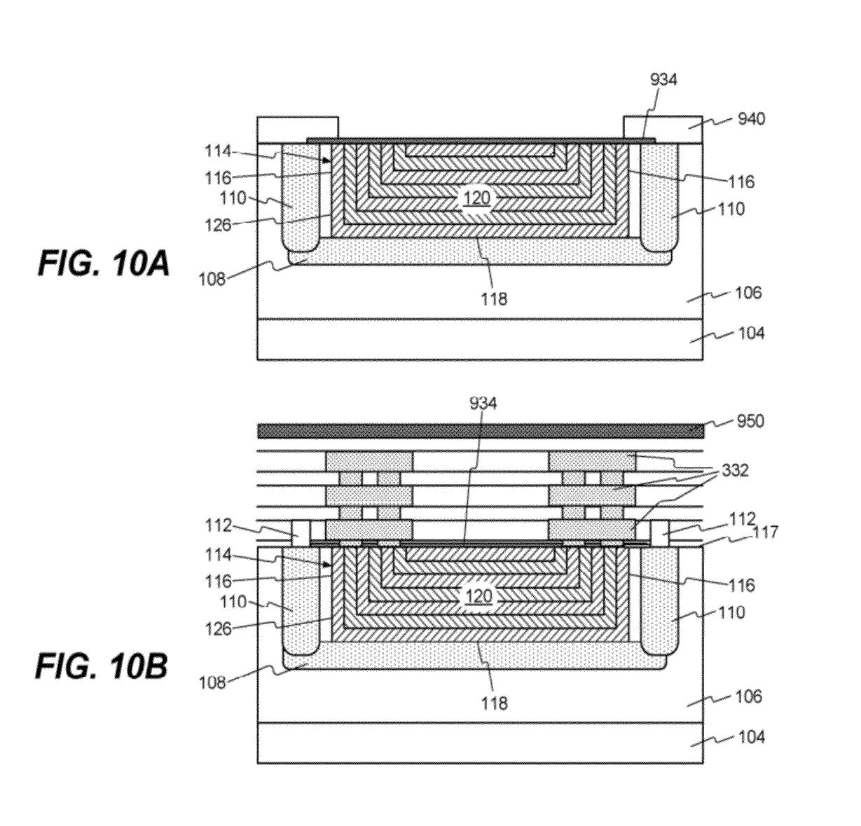

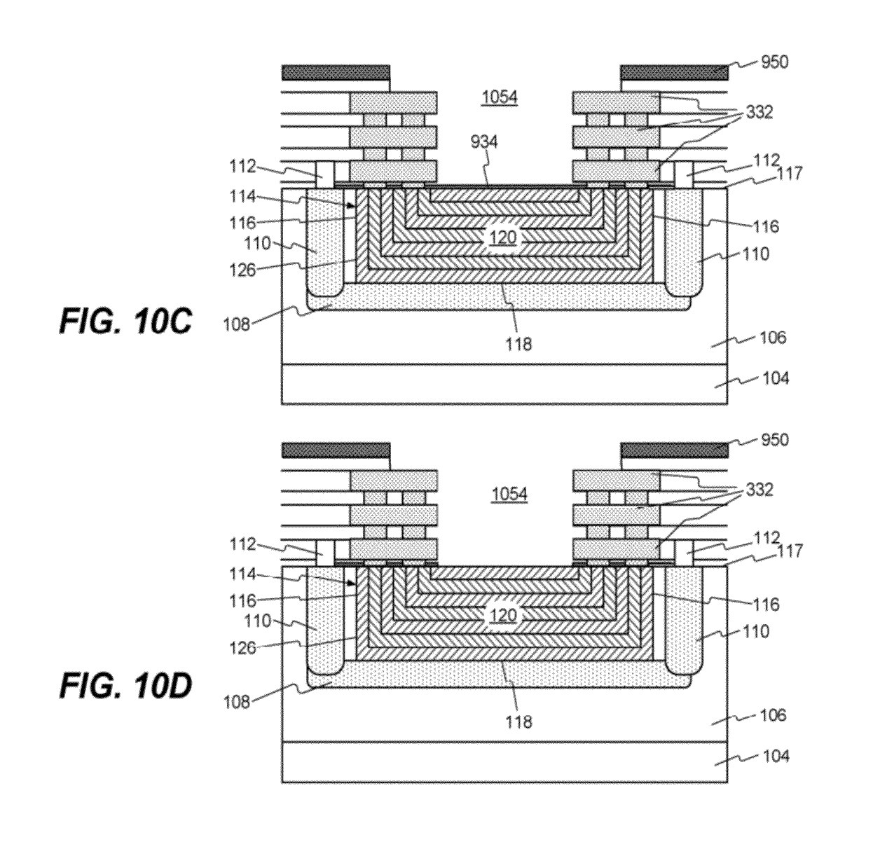

In another fabrication method, the steps described above with respect to FIGS. 9A-9G are carried out. This results in the patterned protection layer 934 over the optical filter 120, and active devices for the optical sensor device being formed along with an ILD 940, as shown in FIG. 9G. As in the previously described method, a portion of the ILD 940 over the optical filter 120 is removed, as shown in FIG. 10A. However, unlike the previously described method, the protection layer 934 is not removed at this point, and thus, the area over optical filter 120 is not exposed at this point, as shown in FIG. 10A. The steps described with respect to FIGS. 9A and 9J are then performed, which results in the structure shown in FIG. 10B. FIG. 10B is the substantially the same as FIG. 9J, except the protection layer 934 is still covering the optical filter 120.

As illustrated in FIG. 10C, an opening 1054 is defined over the optical filter 120, and the various IMD and ILD layers are etched down to an etch stop layer in the form of the protective layer 934. The opening 1054 is self-aligned to metal layers 332. The etch stop/protection layer 934 is then selectively removed over optical filter 120, as shown in FIG. 10D.

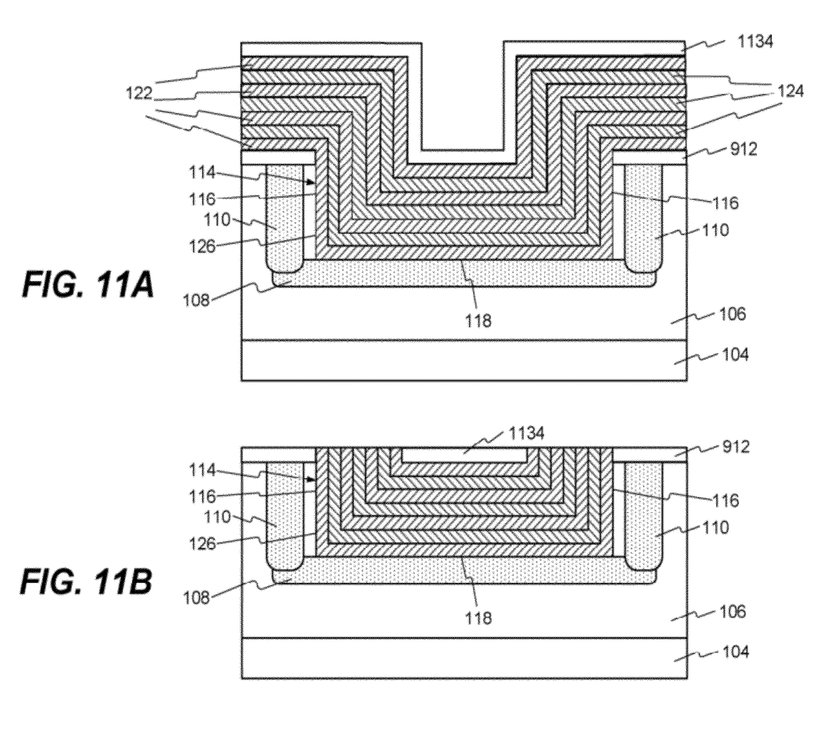

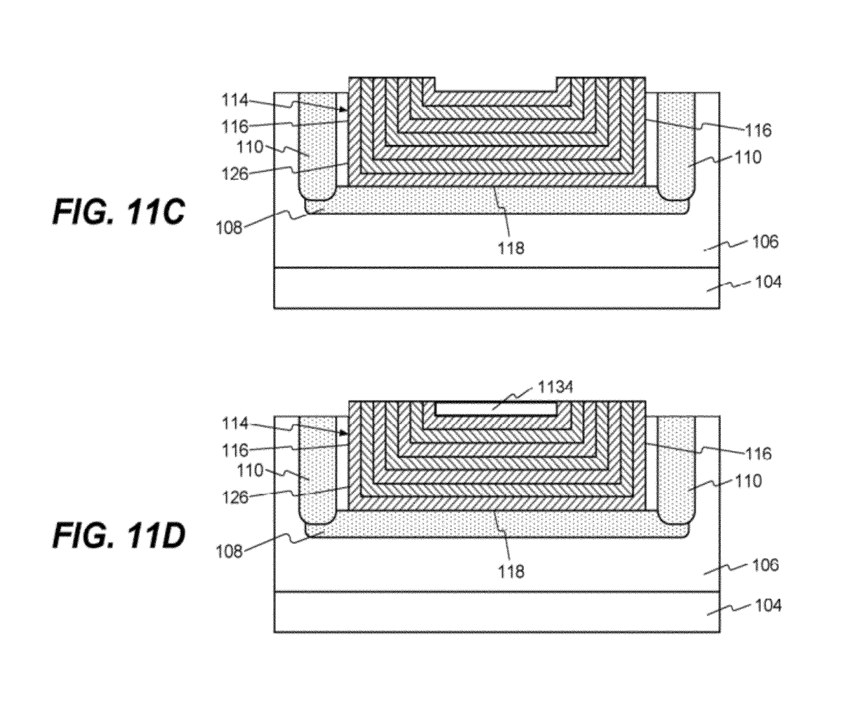

In an alternative fabrication method, the steps described above with respect to FIGS. 9A-9D are carried out. Then, as illustrated in FIG. 11A, an etch stop layer 1134, such as SiN, is formed over the dielectric filter stack to protect optical filter 120. A CMP is then performed to planarize the top surface of the optical filter 120, as shown in FIG. 11B. The CMP breaks through the top of the removal region without affecting etch stop layer 1134. The protective layer 912 and the etch stop layer 1134 protect an Si island and the filter stack from dishing. The protective layer 912 and etch stop layer 1134 are then stripped as shown in FIG. 11C, with the top layer of the filter stack being Si, as SiO₂ will etch off. The exposed vertical SiO₂ edges will be attacked by etches and cleaned. Thereafter, the dielectric layers can be planarized until a top surface of the optical filter 120 is coplanar with a top surface of the substrate 106. Alternatively, etch stop layer 1134 can be patterned so that it is left over optical filter 120, as illustrated in FIG. 11D. Thereafter, the dielectric layers and the etch stop layer 1134 can be planarized until the etch stop layer 1134 is removed and a top surface of the optical filter 120 is coplanar with a top surface of the substrate 106.

In another method, various dummy patterns can be formed over an optical filter area to prevent dishing within the exposed area, particularly if the optical sensor is large.

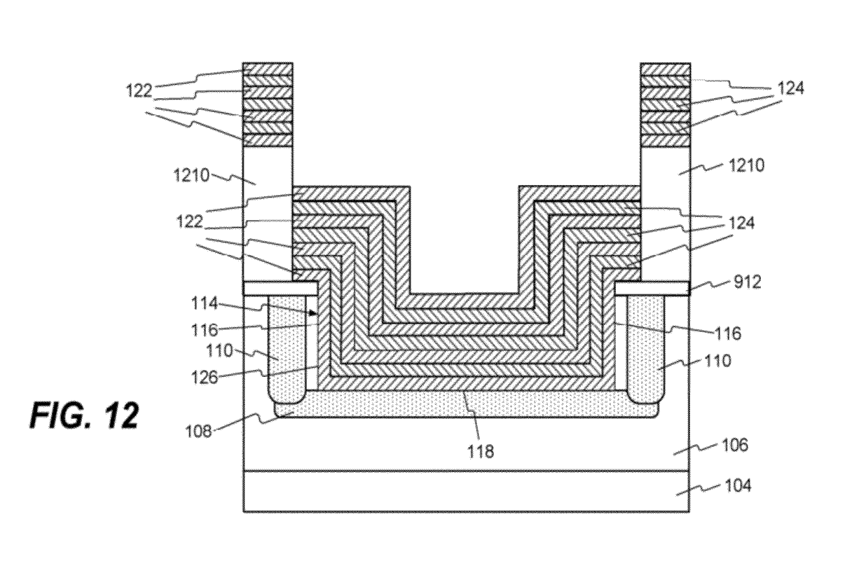

In a further method, the steps described above with respect to FIGS. 9A-9C are carried out. Then the optical filter 120 is formed using a lift-off process. More specifically, referring to FIG. 12, a lift-off resist layer 1210 is patterned, and alternating dielectric layers 122 and 124 (e.g., alternating Si and SiO₂ layers) are deposited in the trench 114 to form the optical filter 120. After the dielectric layer stack is complete, the resist layer 1210 can be removed, which results in the portions of the dielectric layers 122 and 124 above the resist layer 1210 also being removed. Thereafter, the dielectric layers 122 and 124 and the protective layer 912 can be planarized until the top surface of the optical filter 120 is coplanar with a top surface of the protection layer 912. Thereafter, an over etch can be performed to remove the protection layer 912, and further planarization can be performed so that the top surface of the optical filter 120 is coplanar with the top surface of the substrate 106. Further processing, described above with reference to FIGS. 9F-9J and/or 10A-10D, can also be performed.

As mentioned above, the dielectric materials used to form the optical filter 120 (or 220) can include silicon dioxide (SiO2), silicon hydride (SixHy), silicon nitride (SixNy), silicon oxynitride (SixOzNy), tantalum oxide (TaxOy), gallium arsenide (GaAs), gallium nitride (GaN), and the like. Alternating layers in the optical filter may have a constant or varying film thickness throughout the filter stack, in order to achieve the desired optical response. By careful choice of the exact composition, thickness, and number of these layers, it is possible to tailor the reflectivity and transmissivity of the optical filter to produce almost any desired spectral characteristics. For example, the reflectivity can be increased to greater than 99.99%, to produce a high-reflector (HR) coating. The level of reflectivity can also be tuned to any particular value, for instance to produce a mirror that reflects 90% and transmits 10% of the light that falls on it, over some range of wavelengths. Such mirrors have often been used as beam splitters, and as output couplers in lasers. Alternatively, the optical filter can be designed such that the mirror reflects light only in a narrow band of wavelengths, producing a reflective optical filter.

Generally, layers of high and low refractive index materials are alternated one above the other. This periodic or alternating structure significantly enhances the reflectivity of the surface in the certain wavelength range called band-stop, which width is determined by the ratio of the two used indices only (for quarter-wave system), while the maximum reflectivity is increasing nearly up to 100% with a number of layers in the stack. The thicknesses of the layers are generally quarter-wave (then they yield to the broadest high reflection band in comparison to the non-quarter-wave systems composed from the same materials), designed such that reflected beams constructively interfere with one another to maximize reflection and minimize transmission. Using the above described structures, high reflective coatings can achieve very high (e.g., 99.9%) reflectivity over a broad wavelength range (tens of nanometers in the visible spectrum range), with a lower reflectivity over other wavelength ranges, to thereby achieve a desired spectral response. By manipulating the exact thickness and composition of the layers in the reflective stack, the reflection characteristics can be tuned to a desired spectral response, and may incorporate both high-reflective and anti-reflective wavelength regions. The coating can be designed as a long-pass or short-pass filter, a bandpass or notch filter, or a mirror with a specific reflectivity.

In accordance with specific embodiments of the present invention, an optical filter is used to shape the spectral response of the underlying photo detector region to obtain a true human eye spectral response, i.e., a response that is similar to that of a typical human eye response. Alternative spectral responses are possible, and within the scope of the present invention.

In the above described embodiments, the optical filter formed in the trench was generally described as including dielectric mirrors formed of alternating dielectric layers with different optical properties. A benefit of forming a filter using such dielectric layers is that they can withstand front-end-of-line (FEOL) semiconductor fabrication processes including thermal processes at temperatures of up to at least 1,200 degrees Celsius. Additionally, such dielectric layers can be used to produce high performance optical filters. However, the optical sensor devices of embodiments of the present invention can include alternative types of filters, so long as the filters can be formed as part of a FEOL fabrication processes, e.g., so long as such alternative filters can withstand thermal processes at temperatures of up to at least 1,200 degrees Celsius. For example, semiconductor optical filters can be formed as part of a FEOL fabrication process. Such semiconductor optical filters can include alternating semiconductor layers with different bandgaps. Exemplary semiconductor layers that can be used to form a semiconductor optical filter include, but are not limited to, Gallium nitride (GaN), Aluminum gallium nitride (AlGaN), Indium phosphide (InP) and Gallium arsenide (GaAs).

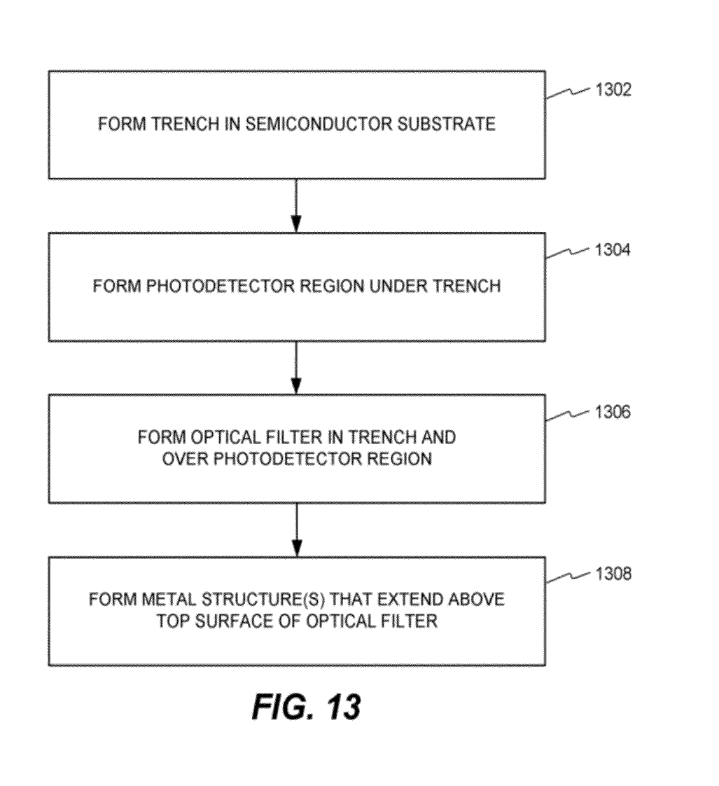

The high level flow diagram of FIG. 13 will now be used to summarize methods for manufacturing monolithic optical sensor devices, in accordance with various embodiments of the present invention. Referring to FIG. 13, at step 1302 a trench (e.g., 114 or 214) is formed in a semiconductor substrate (e.g., 106). The trench can be formed as was described above with reference to FIG. 9B, e.g., after wells (e.g., 110) are formed as was described above with reference to FIG. 9A. More specifically, the trench can be performed using etching. Alternatively, a resists can be patterned onto a substrate, and additional layers of the substrate can be grown around the resist, such that when the resist is removed a trench is formed. Well regions, e.g., similar to well regions 110, can then be formed.

After the trench is formed, at step 1304 a photodetector region is formed under the trench, e.g., as was described above with reference to FIG. 9C. This can include, e.g., forming a cathode layer (e.g., 108) is the substrate, such as by a N+ cathode implant at the bottom of the trench, but is not limited thereto. In the above described FIGS. and discussion, the photodetector regions of the optical sensor devices were generally shown and described as being a vertically-oriented photodiodes, which are also known as vertically-disposed photodiodes. However, the photodetector regions of the optical sensor devices can alternatively be laterally-oriented photodiodes, which are also known as laterally-disposed photodiodes. It is also noted that the photodetector regions can be PN diodes, or PIN diodes.

At step 1306, an optical filter (e.g., 120 or 220) is formed in the trench and over at least a portion of the photodetector region. For example, as was described above with reference to FIGS. 9D and 9E, alternating dielectric layers (e.g., 122 and 124) can be deposited in the trench to form the optical filter.

At step 1308, one or more metal structures that extend above a top surface of the optical filter are formed. Step 1308 can include forming at least one metal connector (e.g., 112) beyond a periphery of the top surface of the optical filter. Additionally, step 1308 can include forming at least one metallization layer (e.g., 128) over at least a portion of the top surface (e.g., 127) of the optical filter (e.g., 120). As was described above with reference to FIGS. 3-8, 9I, 9J and 10B-10D, step 1308 can include forming a plurality of stacked metallization layers connected to one another by one or more metal columns over at least a portion of the top surface of the optical filter.

In accordance with various embodiments, steps 1302, 1304 and 1306 are performed as part of a FEOL semiconductor fabrication process, and step 1308 is performed as part of a BEOL semiconductor fabrication process.

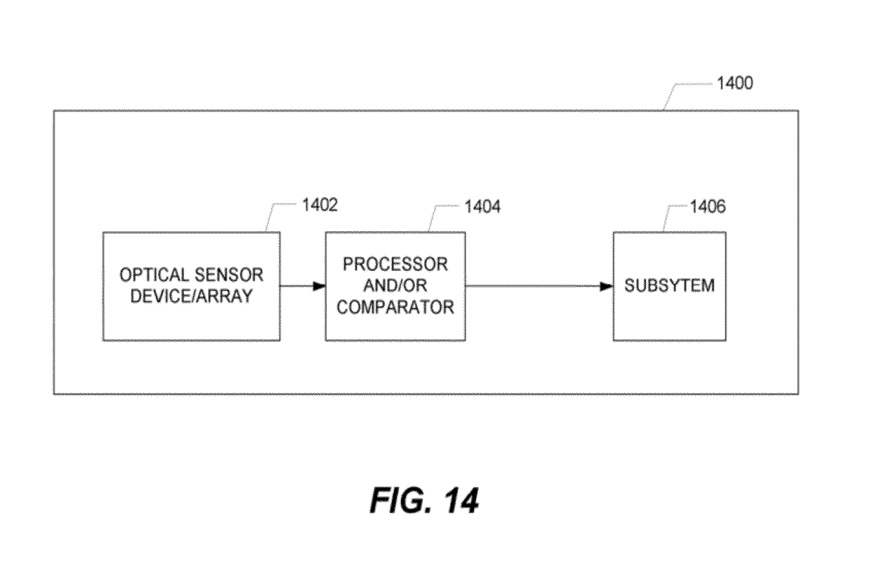

FIG. 14 is a high level block diagram of a system that includes an optical sensor device according to an embodiment of the present invention. Optical sensor devices of embodiments of the present invention can be used in various systems, including, but not limited to, mobile-phones and other handheld-devices, computer systems and/or portions thereof (e.g., computer display monitors).

Referring to the system 1400 of FIG. 14, for example, the optical sensor device/array 1402 (e.g., device 100, 200, 300, 400 or 800, or array 600 or 700) can be used to control whether a subsystem 1406 (e.g., display screen, touch-screen, backlight, virtual scroll wheel, virtual keypad, navigation pad, etc.) is enabled or disabled, and/or to adjust the brightness of the subsystem. For example, a current produced by the optical sensor device 1402 can be converted to a voltage (e.g., by a transimpedance amplifier), and the voltage can be provided to a comparator and/or processor 1404 which can, e.g., compare the voltage to one or more threshold, to determine whether to enable or disable the subsystem, or adjust the brightness of the subsystem. It is also possible that functionality of the transimpedance amplifier, the comparator and/or processor 1404, or portions thereof, be included within the optical sensor device/array 1404. For example, a monolithic optical sensor device can include transimpedance amplifier circuitry as well as other AFE circuitry.

In accordance with an embodiment, one or more of the optical sensor devices (e.g., device 100, 200, 300, 400 or 800, or array 600 or 700) that include a filter (e.g., 120 or 220) described herein can be included in a same die and/or a same system along with one or more further optical sensor devices that is/are covered by a light blocking material (e.g., a metal layer) that does not let any light through. The optical sensors devices that are covered by the light blocking material will produce a current, known as a dark current or a leakage current, that varies with changes in temperature and variations in processing conditions. Similarly, a small portion of the current generated by the optical sensor devices (including a filter 120 or 220) described herein will be due to a dark current, while the remaining portion of the current is primarily indicative of detected light (the wavelengths of which are dependent upon the filter(s)). By forming optical sensors device(s) that are covered by the light blocking material adjacent to the optical sensor device(s) (including a filter 120 or 220) described herein, the dark current generated by optical sensors device(s) covered by the light blocking material can be subtracted from a current generated by the optical sensor device(s) (including a filter 120 or 220) described herein, to remove the affects of the dark current.

Alternatively, or additionally, one or more naked optical sensor devices (that do not include a filter) can be included in a same die and/or a same system along with one or more of the optical sensor devices (including a filter 120 or 220) described herein. The naked optical sensor device(s) will detect both ambient visible light and ambient IR light. Assume the filter(s) 120 or 220 of the optical sensor device(s) described herein are designed to filter out ambient visible light while passing ambient IR light, and thus, produce a current indicative of ambient IR light. By subtracting the current indicative of ambient IR light from the current generated by the naked optical sensor device(s), a current indicative of ambient visible light can be produced. Other variations are also possible, depending upon the filter design and the desired optical response.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

What is claimed is:

1. A monolithic optical sensor device, comprising:
a semiconductor substrate having a trench;
a photodetector region under said trench;
an optical filter in said trench and over at least a portion of said photodetector region; and
one or more metal structures extending above a top surface of said optical filter.

2. The monolithic optical sensor device of claim 1, wherein:
said semiconductor substrate has a top surface down from which sidewalls of said trench extend downward; and
said top surface of said optical filter is coplanar with said top surface of said semiconductor substrate.

3. The monolithic optical sensor device of claim 1, wherein said one or more metal structures include at least one metal connector beyond a periphery of said top surface of said optical filter.

4. The monolithic optical sensor device of claim 3, wherein said one or more metal structures further include at least one metallization layer over at least a portion of said top surface of said optical filter.

5. The monolithic optical sensor device of claim 4, wherein said at least one metallization layer comprises a plurality of stacked metallization layers connected to one another by one or more metal columns.

6. The monolithic optical sensor device of claim 1, wherein said optical filter comprises a dielectric reflective optical coating filter including a plurality of dielectric layers that fill said trench and thereby cover the at least a portion of said photodetector region.

7. The monolithic optical sensor device of claim 6, wherein the plurality of dielectric layers of the dielectric reflective optical coating filter can withstand front-end-of-line (FEOL) semiconductor fabrication processes including thermal processes at temperatures of up to at least 1,200 degrees Celsius.

8. The monolithic optical sensor device of claim 7, wherein the plurality of dielectric layers of the dielectric reflective optical coating filter comprise dielectric layers having a relatively high refractive index alternating with dielectric layers having a relatively lower reflective index.

9. The monolithic optical sensor device of claim 6, wherein the plurality of dielectric layers of the dielectric reflective optical coating filter comprise dielectric materials selecting from the group consisting of:
silicon dioxide (SiO2);
silicon hydride (SixHy);
silicon nitride (SixNy);
silicon oxynitride (SixOzNy);
tantalum oxide (TaxOy);
gallium arsenide (GaAs);
gallium nitride (GaN).

10. The monolithic optical sensor device of claim 1, wherein:
said semiconductor substrate is of a first conductivity type;
a layer of a second conductivity type is formed in said semiconductor substrate under and adjacent to a bottom of said trench; and
said photodetector region is provided, at least in part, by
a portion of said layer of the second conductivity type formed in said semiconductor substrate under and adjacent to said bottom of said trench, and
a portion of said semiconductor substrate of the first conductivity type that is adjacent to said layer of the second conductivity type.

11. The monolithic optical sensor device of claim 10, further comprising:
a further semiconductor substrate of the first conductivity type under the said semiconductor substrate having said trench;
wherein said semiconductor substrate having said trench has a lower doping concentration than said further semiconductor substrate; and
wherein said photodetector region is also provided by a portion of said further semiconductor substrate under said trench.

12. A method for manufacturing a monolithic optical sensor device, comprising:
(a) forming a trench in a semiconductor substrate;
(b) forming a photodetector region under the trench;
(c) forming an optical filter in the trench and over at least a portion of the photodetector region; and
(d) forming one or more metal structures that extend above a top surface of the optical filter.

13. The method of claim 12, wherein
steps (a), (b) and (c) are performed as part of a front-end-of-line (FEOL) semiconductor fabrication process; and
step (d) is performed as part of a back-end-of-line (BEOL) semiconductor fabrication process.

14. The method of claim 12, wherein steps (a), (b) and (c) are performed prior to step (d).

15. The method of claim 14, wherein step (d) comprises forming at least one metal connector beyond a periphery of the top surface of the optical filter.

16. The method of claim 14, wherein step (d) comprises forming at least one metallization layer over at least a portion of the top surface of the optical filter.

17. The method of claim 14, wherein step (d) comprises forming a plurality of stacked metallization layers connected to one another by one or more metal columns over at least a portion of the top surface of the optical filter.

18. The method of claim 12, wherein step (a) comprises forming the trench in the semiconductor substrate using etching.

19. A system, comprising:
a monolithic optical sensor device configured to produce a current indicative of ambient visible light; and
a subsystem that is adjusted in dependence on the current produced by the monolithic optical sensor device;
wherein the monolithic optical sensor device includes
a semiconductor substrate having a trench;
a photodetector region under said trench;
an optical filter in said trench and over at least a portion of said photodetector region; and
one or more metal structures extending above a top surface of said optical filter.

20. The system of claim 19, wherein:
said semiconductor substrate of the monolithic optical sensor device has a top surface down from which sidewalls of said trench extend downward; and
said top surface of said optical filter is coplanar with said top surface of said semiconductor substrate.
